(19) United States
(12) Patent Application Publication
(10) Pub. No.: US 2008/0101023 A1
(43) Pub. Date: May 1, 2008

(54) Negative pressure pump device

(76) Inventor: Hsia-Yuan Hsu, Daya Township (TW)

Correspondence Address: BRUCE H. TROXELL, SUITE 1404, 5205 LEESBURG PIKE, FALLS CHURCH, VA, 22041, US

(21) Appl. No.: 11/590,909

(22) Filed: Nov. 1, 2006

(51) Int. Cl. G06F 1/20; B01D 25/00; H05K 7/20

(52) U.S. Cl. 361/699; 210/805

(57) ABSTRACT

A negative pressure pump device includes a water tank installed with a pump having an entrance connector extended out of the water tank. The water tank has an exit connector and a valve set on its topside. The entrance connector and the exit connector are respectively connected with a connecting tube for connecting with a circulation system. When the pump works with the valve closed, water is filled in the circulation system, the connecting tubes and the pump to make the pressure of a chamber of the water tank become negative, forming a suction force to suck in the water in the entrance connector, not only keeping the pump operate with a less power for saving energy, but also using less the connecting tubes for decreasing possibility of leakage.

### BACKGROUND OF THE INVENTION

1. Field of the Invention

This invention relates to a pump device, particularly to one able to create a situation of negative pressure.

2. Description of the Prior Art

Commonly, a traditional pump device includes a water entrance and a water exit. A water entry tube is linked between the water exit and a circulation system, such a CPU cooler system of a computer and a filtration system. The circulation system is then connected to a water tank via a connecting tube. The water tank is connected with a pump through a water exit tube. Of course, the water tank is filled properly with water so that a circulation can be established. As the pump is turned on to work, water in the water tank is to be sucked to the circulation system. But, among the pump, the circulation system and the water tank, various tubes are the only connecting material for linking them one another, apt to cause leakage at connections owing to low quality of material or a tough installation because of too many tubes.

### SUMMARY OF THE INVENTION

The objective of this invention is to offer a pump device with a negative pressure situation.

The main characteristics of the invention are a water tank and a pump. The pump is installed inside the water tank so that not a connecting tube is needed to link the water tank and the pump, able to reduce connections in the invention for lessening possibility of leakage. The pump is provided with an entrance connector extended upwards to penetrate out of the water tank. The water tank has an exit connector and a valve set on its topside. The entrance connector and the exit connector are respectively connected with a connecting tube for connecting with a circulation system. When the pump is turned on to operate with the valve closed, water is to be sucked from the water tank to flow in the circulation system, the connecting tubes and the pump to make the pressure of a chamber of the water tank to become negative so as to generate a suction force to automatically suck in the water in the entrance connector to form a circulating cycle, able to keep the pump running with a less power for saving energy.

### BRIEF DESCRIPTION OF DRAWINGS

This invention is better understood by referring to the accompanying drawings, wherein:

FIG. 1 is a block chart of a first preferred embodiment of a negative pressure pump device in the present invention;

FIG. 2 is a block chart of a second preferred embodiment of a negative pressure pump device in the present invention; and

FIG. 3 is a block chart of a third preferred embodiment of a negative pressure pump device in the present invention.

### DETAILED DESCRIPTION OF THE PREFERRED EMBODIMENT

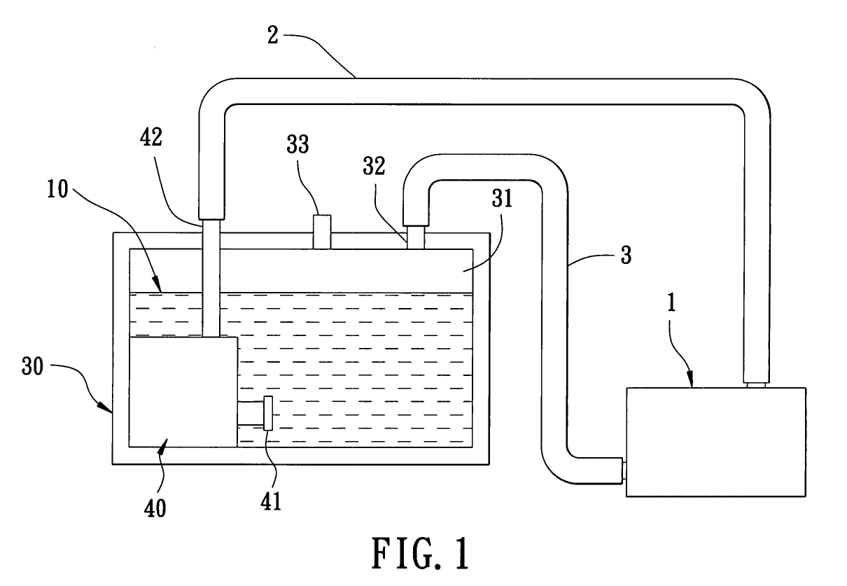

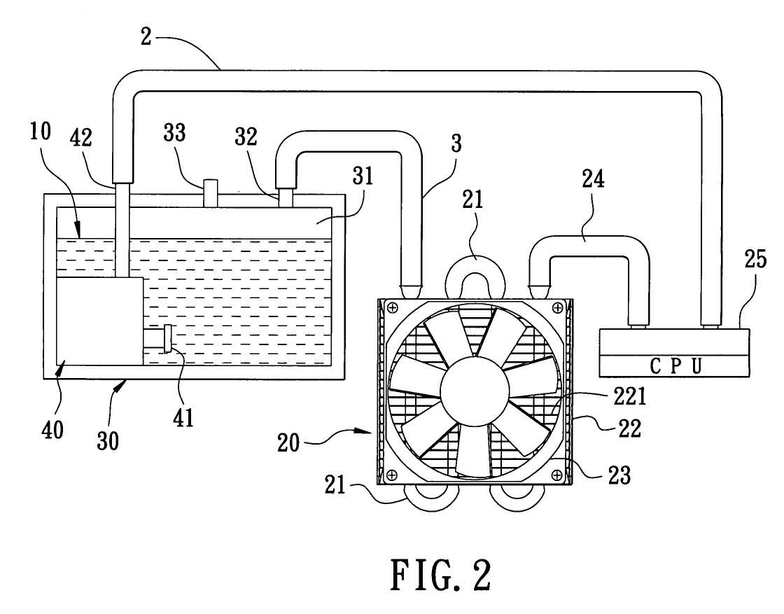

As shown in FIGS. 1 and 2, a first preferred embodiment of a negative pressure pump device in the present invention is connected with a circulation system 1 via a water entry tube 2 and a water exit tube 3, enabling water 10 to cycle between the circulation system 1 and the negative pressure pump device. The circulation system 1 in the invention is a cooling circulation device 20. The negative pressure pump device includes a water tank 30 and a pump 40.

The water tank 30 formed of a certain size and a proper shape is provided with a chamber 31 inside it for containing water filled up to a definite level and added with a cooling agent. An entrance connector 32 and a valve 33 are also set respectively at a preset position of an upper portion of the water tank 30. The water exit tube 3 of the circulation system 1 is connected with the entrance connector 32 at its one end and connected with a cooling tube 21 of the cooling circulation device 20 at the other end, allowing water 10 to flow through. The cooling tube 21 is installed fixedly among plural cooling plates 221 confined in a cooling frame 22, which is fixed with a fan 23 too. The other end of the cooling tube 21 is linked to a cooling base 25 by means of a connecting tube 24. The cooling base 25 is attached to a CPU for dispersing heat and connected with the water entry tube 2. By closing or opening the valve 33 of the water tank 30, the water 10 can be supplied to the water tank 30 or the pressure in the water tank 30 can be balanced.

The pump 40 installed at a preset location of the bottom of the water tank 30 is provided with an entrance 41 and an exit connector 42 located at preset positions. The exit connector 42 is extended upwards to penetrate through the topside of the water tank 30 and sealed tightly with the water tank 30 to prevent any leakage from happening. When the pump 40 starts working, the water 10 in the water tank 30 is sucked from the entrance 41 to run into the exit connector 42 and then, to the water entry tube 2, the cooling circulation device 20 of the circulation system 1, the water exit tube 3, the entrance connector 32 and the water tank 30 orderly. Therefore, suppose the valve 33 is closed, the pressure in the chamber 31 is kept steady. But, as soon as the pump 40 is turned on to suck continuously the water 10 from the water tank 30 to keep the water entry tube 2 and the water exit tube 3 full of the water 10, the pressure in the chamber 31 is to become negative, so that the chamber 31 is to generate a suction force to suck the water 10 in the water exit tube 3 to run into the water tank 30.

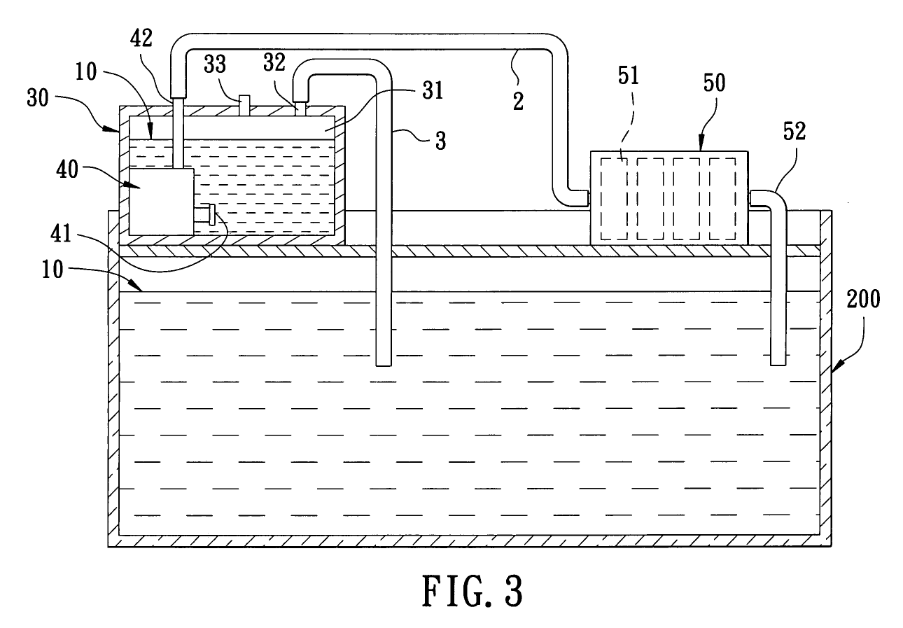

As shown in FIG. 3, a second preferred embodiment of a negative pressure pump device in the present invention has the same components except that the cooling circulation device 20 of the circulation system 1 in the first embodiment is replaced with a filtration circulation device 50. When the pump 40 is turned on to suck in the water 10 in the water tank 30 from the entrance 41, the chamber 31 of the water tank 30 is to have a negative pressure so as to suck in the water 10 stored in a reservoir 200 through the water exit tube 3. Of course, the water 10 is to pass through the water entry tube 2 and then, to the filtration circulation device 50, which is provided with plural filtrating elements 51 for filtrating the water 10. Finally, the water 10 is to run through a connecting tube 52 set at the other side of the filtration circulation device 50 and then, into the reservoir 200.

As shown in FIGS. 2 and 3, the pump 40 can also be formed integrally with the water tank 30 at a preset location. As described in the first and the second embodiments with the valve 33 closed, when the pump 40 is turned on to suck at the beginning, the water 10 is to be filled with the water entry tube 2 and the water exit tube 3 to keep the chamber 31 airtight. As long as the pump 40 keeps on running, the water 10 is to be sucked into the pump 40 through the entrance 41 to make the chamber 31 form a negative pressure, which generates spontaneously a sucking force to suck the water 10 in the water exit tube 3 of the circulation system 1 to run into the water tank 30. In addition, since the pump 40 is emerged in the water tank 30, the water 10 can be sucked into the pump 40 via the entrance 41 instead of a connecting tube needed to be linked between the water tank 30 and the pump 40 as the traditional one does, able to decrease connections among the components in the invention for reducing possibility of leakage.

The invention has the following advantages as can be seen from the foresaid description.

1. The water entry tube 2 and the water exit tube 3 are filled with the water 10 at the beginning of the operation of the pump 40, keeping the chamber 31 airtight and negative in its pressure, which generates spontaneously a sucking force to suck the water 10 in the water exit tube 3. Therefore, in favor of the sucking force, the pump 40 can run with a less power for saving energy.

2. Because the pump 40 is positioned in the water tank 30, there is no need to connect the water tank 30 and the pump 40 with an additional tube, able to decrease connections among the components in the invention for reducing possibility of leakage.

3. Owing to the pump 40 contained in the water tank 30, the invention has a rather small bulk for installing with convenience and saving a manufacturing cost.

While the preferred embodiment of the invention has been described above, it will be recognized and understood that various modifications may be made therein and the appended claims are intended to cover all such modifications that may fall within the spirit and scope of the invention.

What is claimed is:

1. A negative pressure pump device to be connected with a circulation system by means of a water entry tube and a water exit tube to keep water cycled between said circulation system and said pump device, said pump device comprising:
a water tank having a certain size and a proper shape and provided with a chamber inside it for filling water up to a definite level, an entrance connector and a valve set respectively at a preset position of an upper portion of said water tank, said entrance connector connected with said water exit tube of said circulation system, said water tank able to be supplied with water or to be balanced with its pressure by closing or opening said valve of said water tank;
a pump installed at a preset location of a bottom of said water tank and provided with an entrance connector and an exit connector located at preset positions, said exit connector extended upwards to penetrate through a top side of said water tank and sealed tightly with said water tank without suspicion of leakage, said water in said water tank sucked from said entrance to run through said exit connector, said water entry tube, said circulation system, said water exit tube, said entrance connector and said water tank back circularly by sucking force generated by operation of said pump; and
said water entry tube and said water exit tube filled with said water to keep said chamber of said water tank airtight with a definite pressure in case of said valve of said water tank kept closed while turning on said pump, the pressure in said chamber of said water tank gradually becoming negative to generate a suction force to suck water from said water exit tube when said pump is continuing to operate.

2. A negative pressure pump device as claimed in claim 1, wherein said circulation system is a cooling circulation device that includes a fan installed on a cooling frame, said cooling frame provided with plural cooling plates connected with a cooling tube among them, said cooling tube connected with said water exit tube at its one end and connected with a connecting tube liked to a cooling base at the other end, said cooling base connected with said water entry tube.

3. A negative pressure pump device as claimed in claim 1, wherein said cooling base is connected with a CPU of a computer.

4. A negative pressure pump device as claimed in claim 1, wherein said circulation system is a filtration circulation device that is able to suck in water to be filtered from said entrance by a suction force of said pump, said water to be filtered and stored in a reservoir sucked automatically into said water tank owing to a negative pressure formed in said water tank, said water to be filtered running through plural filtrating elements of said filtration circulation device and then, back to said reservoir again via a connecting tube connected at the other end of said filtration circulation device.

5. A negative pressure pump device as claimed in claim 1, wherein said water is added with a cooling agent having a high heat conduction coefficient.
